(19) United States
(12) Patent Application Publication
(10) Pub. No.: US 2007/0216421 A1
(43) Pub. Date: Sep. 20, 2007

(54) Method of Generating High Voltages at Low Frequencies Using Small Transformers

(76) Inventor: Shary Nassimi, Malibu, CA (US)

Correspondence Address: BOND, SCHOENECK & KING, PLLC, ONE LINCOLN CENTER, SYRACUSE, NY, 13202-1355, US

(21) Appl. No.: 11/308,256

(22) Filed: Mar. 14, 2006

(51) Int. Cl. G01R 27/28

(52) U.S. Cl. 324/618

(57) ABSTRACT

A method of providing an operating signal to an electrical device such as a telephone or FAX machine at a prescribed voltage and frequency, e.g., 100 volts at 25 Hz. Electrical power is generated as DC and converted to AC at a voltage substantially below the prescribed voltage. This signal is applied to the input stage of a boost transformer with the signal at the output stage being substantially equal to the prescribed voltage at a frequency substantially higher than the prescribed frequency, e.g., 2,500 Hz. The signal at the output stage is modulated to provide periods of 1/25 Hz duration alternating between the high voltage, high frequency signal and no signal, i.e., periods of silence or zero voltage, before being applied to the target device. Since that device is designed not to respond to the high frequency signals, the effect is that of a signal being applied at a 25 Hz frequency.

### BACKGROUND OF THE INVENTION

The present invention relates to methods of operating electrical transformers, and more specifically to the use of transformers of relatively small size capable of generating relatively high voltages at relatively low frequencies.

Some electrical apparatus, including telephony devices, requires generation of relatively high voltages at low frequency. For example, a typical FAX/Phone Switching Device requires generation of a “Ring Voltage” of about 100 volts at an FCC prescribed “Ring Frequency,” of 25 Hz. To generate such voltages at such frequencies using the DC power present in most conventional devices, the DC is converted to AC using various methods. The voltage is then boosted by applying the AC current and voltage to a “boost transformer” which is sized appropriately for the desired, boost voltage and for the frequency of the AC voltage applied. Boosting with transformers at low frequencies is very inefficient, requiring transformers of relatively large size and high cost; due to their size, such transformers are also relatively heavy. Thus, to generate the voltages required at the desired frequencies, typical telephony devices employ relatively large, heavy and expensive transformers.

It is a principal object of the present invention to provide a method of operating a transformer which permits the use of smaller, lighter and less expensive transformers than those previously employed in comparable applications.

Another object is to provide a novel and improved approach to transforming electrical power to provide a signal at relatively high voltage and low frequency using a relatively small, efficient and low cost transformer.

A further object is to provide a telephony device responsive to a predetermined voltage and frequency wherein the voltage and frequency are provided using a transformer which is smaller, lighter and less expensive than those used in comparable prior art telephony devices.

Other object will in part be obvious and will in part appear hereinafter.

### SUMMARY OF THE INVENTION

It is known that the higher the frequency of the output voltage of a transformer, the smaller, lighter and cheaper the transformer may be. Therefore, transformers used in applications such as telephony switching devices, typically requiring a signal of about 100 volts at about 25 Hz, are just the opposite, i.e., larger, heavier and more costly. The present invention addresses this problem by using as the transformer input a relatively high frequency for the voltage which is to be boosted to a higher level. In the example used, instead of inputting 25 Hz, the frequency to be applied to the FAX/Phone Switching Device, a frequency of 2500 Hz is applied at the primary input of the transformer. However, the 2500 Hz signal is applied for 1/25th Hz periods, alternated with 1/25th Hz periods of no signal (silence). Thus, the frequency of the voltage perceived by the telephony device, i.e., the signal at the transformer secondary, is 25 Hz. Since telephony devices are designed to respond to low frequency signals, the 2500 Hz signal is perceived as a high voltage period, alternated with periods of zero voltage.

The invention is also described in an alternate form wherein, rather than discrete periods of voltage at high frequency which are alternated with period of zero voltage, the input to the transformer primary is applied in a sequence of different frequencies at equal time periods. This allows the transformer output to closer mimic the target product's voltage and frequency input requirements. The resulting output is that of a complex waveform closely approximating a sine wave.

The invention can be adapted to any device requiring voltage boost wherein a lighter and lower cost transformer is desirable, while achieving high efficiency with smaller size.

Features of construction and operation of the invention will be more readily understood and fully appreciated from the following detailed disclosure, taken in conjunction with the accompanying drawings.

### BRIEF DESCRIPTION OF THE DRAWINGS

FIG. 1 is a block diagram showing major elements of a system wherein the present invention is employed;

FIG. 2 is a schematic illustration of an electrical waveform applied as the input to the primary of a transformer built and operated in accordance with the present invention;

FIG. 3 is a schematic illustration of the waveform at the transformer output, and applied as an input to a powered device, e.g., a telephony device, as perceived by such device;

FIG. 4 is a schematic illustration of an electrical waveform applied as an input signal to the primary of a transformer in an alternative embodiment; and

FIG. 5 is a schematic illustration of an example of a waveform at the output of a transformer having the waveform of FIG. 3 as an input, as perceived at the input of the target device.

### DETAILED DESCRIPTION

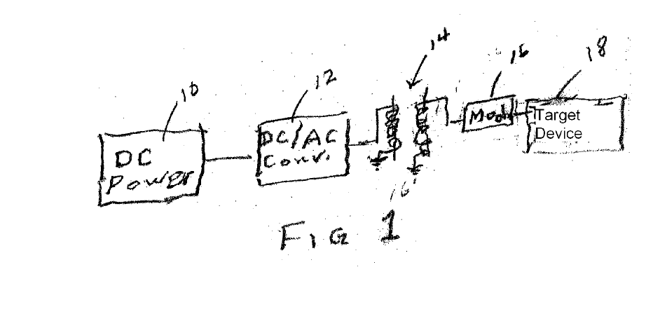

In the block diagram of FIG. 1, a battery or other source of DC power is represented by the block indicated by reference numeral 10. Power source 10 is connected to DC/AC converter 12 wherein the DC power is converted to AC at, for example, 12 volts at a frequency of 2500 Hz. The output of converter 12 is connected to the primary of transformer 14. The voltage is boosted by transformer 14 by a factor of 8, whereby the output of the transformer secondary is about 100 volts. The 2500 Hz frequency is modulated by modulator 16 at a frequency of 25 Hz. That is, the output of modulator 16 is a series of signal impulses comprising periods of silence followed by periods of a signal having a frequency of 2500 Hz, the periods being of equal duration of 1/25^{th} of 2500 Hz. Modulator 16 is connected to target device 18, e.g., a fax machine or telephone requiring a ring signal at 100 volts and a federally mandated frequency of 25 Hz. Since the frequency of the signal applied to the transformer is much higher than the frequency of the signal applied to the target device, the size of the transformer may be small and the efficiency of the boost is highly increased.

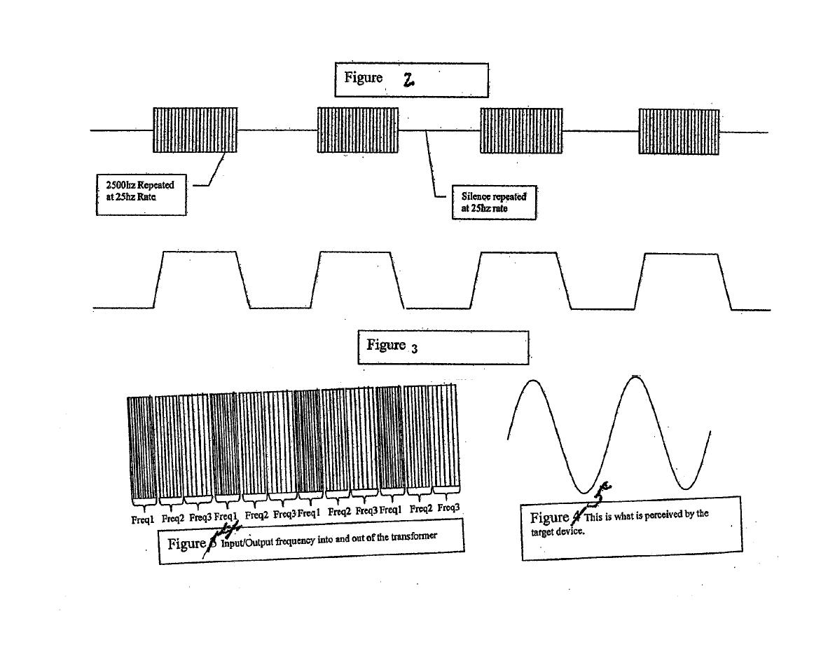

FIG. 2 illustrates the waveform at the output stage of transformer 14. A 25 volt signal at 2500 Hz is present for 1/25^{th} Hz, followed by a period of zero volts (silence).for a period of like duration. That is, periods of high frequency signals, separated in time by periods of no signal, are modulated at a low frequency rate. FIG. 3 represents the waveform as perceived by target device 18. Since the target (telephony) device is not designed to respond to signals with high frequencies, the high frequency signal is perceived by the device as a high voltage period while the period of silence is perceived, as intended, as a zero voltage period. That is, the device perceives spaced periods of voltage signals repeated at a 25 Hz rate, thus giving the equivalent of a 25 Hz signal at 100 volts, the voltage and frequency values necessary for operation of target device 18.

The invention may be applied to any product requiring voltage boost with an output signal at low frequency from a smaller, lighter and less costly transformer while achieving high efficiency. The waveform of FIG. 4 illustrates an input signal to the transformer at three frequencies, i.e., a first frequency, the highest of the three, a second, intermediate frequency, and a third frequency, the lowest of the three, applied at successive periods of equal duration. The changing frequency causes the transformer to operate with an efficiency which varies in accordance with the frequency being used and the center frequency of the transformer. The resulting output signal is a complex waveform, represented in FIG. 5, which closely approximates a sine wave, at the voltage and frequency required by the target device.

What is claimed is:

1. The method of providing an operating signal at a desired voltage and frequency to a target device, said method comprising:
a) applying electrical power at a first voltage, less than said desired voltage, to the input stage of a transformer;
b) boosting said first voltage to a second voltage, substantially equal to said desired voltage, at a frequency which is high relative to said desired frequency, thereby providing a high voltage, high frequency signal at the output stage of said transformer;
c) modulating said high frequency signal at a rate substantially equal to said desired frequency to alternate between periods of signal at said high frequency and said second voltage and periods of no signal to provide said operating signal.

2. The method of claim 1 wherein said target device is a telephony device.

3. The method of claim 2 wherein said desired voltage is about 100 volts and said desired frequency is about 25 Hz.

4. The method of claim 3 wherein said first voltage is about 8 volts.

5. The method of claim 1 wherein said electrical power is generated as DC and is converted to AC prior to being applied to said input stage of said transformer.

6. The method of providing an operating signal to an electrical device, said method comprising:
a) applying electrical power at a first voltage and a plurality of different frequencies, each of said frequencies being applied for successive time periods of substantially equal duration, to the input stage of a transformer;
b) boosting said first voltage to a second voltage at the output stage of said transformer; and
c) said plurality of frequencies being present at said output stage for successive time periods of substantially equal duration and applied as said operating signal to said electrical device.

7. The method of claim 6 wherein the number of said plurality of frequencies is three.

8. The method of claim 6 wherein said operating signal is a complex wave form closely resembling a sine wave.
